(19) United States
(12) Patent Application Publication
(10) Pub. No.: US 2011/0095410 A1
(43) Pub. Date: Apr. 28, 2011

(54) WAFER LEVEL SEMICONDUCTOR DEVICE CONNECTOR

(75) Inventor: Jocel P. Gomez, Lapu-Lapu City (PH)

(73) Assignee: Fairchild Semiconductor Corporation, South Portland, ME (US)

(21) Appl. No.: 12/607,787

(22) Filed: Oct. 28, 2009

(51) Int. Cl. H01L 23/495; H01L 23/538; H01L 23/544

(52) U.S. Cl. 257/676; 257/773; 257/797; 257/E23.169; 257/E23.179; 257/E23.031

(57) ABSTRACT

This document discusses, among other things, a semiconductor connector including a conductive pad in a recessed pad area on a surface of a dielectric, the dielectric material configured to be activated to conductive plating deposition using laser ablation.

### BACKGROUND

Various semiconductor molding compounds can be used to encapsulate a semiconductor die including a transistor, an integrated circuit (IC), or one or more other semiconductor devices, and to provide one or more terminals for coupling the semiconductor device to a circuit board or one or more other materials or devices configured to receive the semiconductor device. In certain examples, a semiconductor connector can be configured to couple one or more contacts of the semiconductor die to one or more terminals of the semiconductor package.

### OVERVIEW

This document discusses, among other things, a semiconductor connector including a conductive pad in a recessed pad area on a surface of a dielectric, the dielectric material configured to be activated to conductive plating deposition using laser ablation. In certain examples, the semiconductor connector can be configured to couple one or more contacts of a semiconductor die to one or more terminals of a leadframe (e.g., one or more terminals of a semiconductor package).

In Example 1, a semiconductor connector includes a dielectric having a first dielectric surface and a second dielectric surface opposite the first dielectric surface, the dielectric configured to be activated to copper (Cu) plating deposition using laser ablation, a first pad having a first shape in a first recessed pad area in the first dielectric surface, the first pad configured to couple a first contact of a semiconductor die to a first terminal of a leadframe, a second pad having a second shape in a second recessed pad area in the first dielectric surface, the second shape different than the first shape, and the second pad configured to couple a second contact of the semiconductor die to a second terminal of the leadframe, a vision marker in a recessed vision marker area in the second dielectric surface, wherein the first and second recessed pad areas includes respective first and second recesses created using laser ablation of the first dielectric surface, and wherein the recessed vision marker area includes a recess created using laser ablation of the second dielectric surface, and wherein the gate pad, the source pad, and the vision marker include laser activated Cu plating depositions.

In Example 2, the vision marker of Example 1 is optionally configured to provide semiconductor connector position information.

In Example 3, the vision marker of any one or more of Examples 1-2 optionally includes separate first and second vision markers configured to provide semiconductor connector position information.

In Example 4, the first conductive pad of any one or more of Examples 1-3 optionally includes a source pad configured to be coupled to a source contact of the semiconductor die and to a source terminal of the leadframe, and the second conductive pad of any one or more of Examples 1-2 optionally includes a gate pad configured to be coupled to a gate contact of the semiconductor die and to a gate terminal of the leadframe.

In Example 5, the semiconductor connector of any one or more of Examples 1-4 optionally includes a wafer-level semiconductor connector, and wherein the wafer-level semiconductor connector is one of a plurality of wafer-level semiconductor connectors on a single wafer, and each of the wafer-level semiconductor connectors of any one or more of Examples 1-4 optionally includes a vision marker configured to provide a boundary for the wafer-level semiconductor connector in relation to the plurality of wafer-level connectors on the single wafer.

In Example 6, the semiconductor connector of any one or more of Examples 1-5 optionally includes a dielectric having a first dielectric surface and a second dielectric surface opposite the first dielectric surface, the dielectric configured to be activated to conductive plating deposition using laser ablation, and a conductive pad in a recessed pad area in the first dielectric surface, the conductive pad configured to couple at least one contact of a semiconductor die to at least one terminal of a leadframe.

In Example 7, the recessed pad area of any one or more of Examples 1-6 optionally includes a recess created using laser ablation of the first dielectric surface, and the conductive pad of any one or more of Examples 1-6 optionally includes a laser activated conductive plating deposition in the recessed pad area.

In Example 8, the dielectric of any one or more of Examples 1-7 optionally includes a polymer configured to be activated to copper (Cu) plating deposition using laser ablation, and the conductive pad of any one or more of Examples 1-7 optionally includes a laser activated Cu plating deposition.

In Example 9, the semiconductor connector of any one or more of Examples 1-8 optionally includes a vision marker in a recessed vision marker area in the second dielectric surface, wherein the vision marker includes a laser activated conductive plating deposition in the recessed vision marker area.

In Example 10, the dielectric of any one or more of Examples 1-9 optionally includes a polymer configured to be activated to copper (Cu) plating deposition using laser ablation, and the vision marker of any one or more of Examples 1-9 optionally includes a laser activated Cu plating deposition.

In Example 11, the vision marker of any one or more of Examples 1-10 optionally includes a first and a second vision marker configured to provide semiconductor connector position information.

In Example 12, the conductive pad of any one or more of Examples 1-11 optionally includes a first conductive pad having a first shape in a first recessed pad area in the first dielectric surface, a second conductive pad having a second shape in a second recessed pad area in the first dielectric surface, the second shape different than the first shape, wherein the first and second conductive pads are configured to couple first and second contacts of the semiconductor die to respective first and second terminals of the leadframe.

In Example 13, the first conductive pad of any one or more of Examples 1-12 optionally includes a source pad configured to be coupled to a source contact of the semiconductor die and to a source terminal of the leadframe, and the second conductive pad of any one or more of Examples 1-12 optionally includes a gate pad configured to be coupled to a gate contact of the semiconductor die and to a gate terminal of the leadframe.

In Example 14, the dielectric of any one or more of Examples 1-9 optionally includes at least one of an epoxy mold compound (EMC), polybutylene terephthalate (PBT), thermoplastic, or crosslink.

In Example 15, the semiconductor connector of any one or more of Examples 1-14 optionally includes a wafer-level semiconductor connector, wherein the wafer-level semiconductor connector is one of a plurality of wafer-level semiconductor connectors on a single wafer, wherein each of the wafer-level semiconductor connectors includes a vision marker configured to provide a boundary for the wafer-level semiconductor connector in relation to the plurality of wafer-level connectors on the single wafer.

In Example 16, a system includes a semiconductor die having a plurality of electrical contacts, a leadframe having a plurality of terminals, and a semiconductor connector configured to couple at least one of the plurality of electrical contacts of the semiconductor die to at least one of the plurality of terminals of the leadframe, the semiconductor connector optionally including a dielectric having a first dielectric surface and a second dielectric surface opposite the first dielectric surface, the dielectric configured to be activated to conductive plating deposition using laser ablation, and a conductive pad in a recessed pad area in the first dielectric surface, the conductive pad configured to couple the at least one of the plurality of electrical contacts of the semiconductor die to the at least one of the plurality of terminals of the leadframe.

In Example 17, the recessed pad area of any one or more of Examples 1-16 optionally includes a recess created using laser ablation of the first dielectric surface, and the conductive pad of any one or more of Examples 1-16 optionally includes a laser activated conductive plating deposition in the recessed pad area.

In Example 18, the system of any one or more of Examples 1-17 optionally includes a vision marker in a recessed vision marker area in the second dielectric surface, wherein the vision marker optionally includes a laser activated conductive plating deposition in the recessed vision marker area.

In Example 19, the conductive pad of any one or more of Examples 1-18 optionally includes a first conductive pad having a first shape in a first recessed pad area in the first dielectric surface, a second conductive pad having a second shape in a second recessed pad area in the first dielectric surface, the second shape different than the first shape, wherein the first and second conductive pads are configured to couple first and second contacts of the semiconductor die to respective first and second terminals of the leadframe.

In Example 20, the semiconductor die of any one or more of Examples 1-19 optionally includes a source contact and a gate contact, the leadframe of any one or more of Examples 1-19 optionally includes a source terminal and a gate terminal, the first conductive pad of any one or more of Examples 1-19 optionally includes a source pad configured to be coupled to the source contact and to the source terminal, and the second conductive pad of any one or more of Examples 1-9 optionally includes a gate pad configured to be coupled to the gate contact to the gate terminal.

In Example 21, a method of forming a semiconductor connector includes providing a first recessed pad area in a first dielectric surface of a dielectric configured to be activated to copper (Cu) plating deposition using laser ablation, providing a second recessed pad area in the first dielectric surface, the second recessed pad area different than the first recessed pad area, providing a recessed vision marker area in a second dielectric surface of the dielectric, forming a first Cu pad in the first recessed pad area, the first Cu pad configured to couple a first contact of a semiconductor die to a first terminal of a leadframe, forming a second Cu pad in the second recessed pad area, the second Cu pad configured to couple a second contact of the semiconductor die to a second terminal of the leadframe, and forming a Cu vision marker in the recessed vision marker area, wherein the providing the first and second recessed pad areas includes using laser ablation of the first dielectric surface, and wherein the providing the recessed vision marker area includes using laser ablation of the second dielectric surface.

In Example 22, the method of any one or more of Examples 1-21 optionally includes providing semiconductor connector position information using the vision marker.

In Example 23, the forming the Cu vision marker of any one or more of Examples 1-9 optionally includes forming separate first and second vision markers configured to provide semiconductor position information.

In Example 24, the providing the first recessed pad area of any one or more of Examples 1-23 optionally includes providing a source pad area, the forming the first Cu pad of any one or more of Examples 1-23 optionally includes forming a Cu source pad configured to be coupled to a source contact of the semiconductor die and to a source terminal of the leadframe, the providing the second recessed pad area of any one or more of Examples 1-23 optionally includes providing a gate pad area, and the forming the second Cu pad of any one or more of Examples 1-23 optionally includes forming a Cu gate pad configured to be coupled to a gate contact of the semiconductor die and to a gate terminal of the leadframe.

In Example 25, the method of any one or more of Examples 1-24 optionally includes providing a recessed pad area in a first dielectric surface of a dielectric configured to be activated to conductive plating deposition using laser ablation, and forming a conductive pad in the recessed pad area in the first dielectric surface, the conductive pad configured to couple at least one contact of a semiconductor die to at least one terminal of a leadframe.

In Example 26, the providing the recessed pad area of any one or more of Examples 1-25 optionally includes using laser ablation of the first dielectric surface, and the forming the conductive pad of any one or more of Examples 1-25 optionally includes using a laser activated conductive plating deposition.

In Example 27, the providing the recessed pad area of any one or more of Examples 1-26 optionally includes using laser ablation of the first dielectric surface of a dielectric configured to be activated to copper (Cu) plating deposition using laser ablation, and the forming the conductive pad of any one or more of Examples 1-26 optionally includes using a laser activated Cu plating deposition.

In Example 28, the providing the recessed pad area in the first dielectric surface of any one or more of Examples 1-27 optionally includes providing a first recessed pad area and a second recessed pad area, the forming the conductive pad of any one or more of Examples 1-27 optionally includes forming a first conductive pad in the first recessed pad area and a second conductive pad in the second recessed pad area, wherein the first conductive pad is configured to couple a first contact of the semiconductor die to a first terminal of the leadframe and the second conductive pad is configured to couple a second contact of the semiconductor die to a second terminal of the leadframe.

In Example 29, the providing the first recessed pad area includes providing a first recessed pad area having a different shape than the second recessed pad area.

In Example 30, the forming the first and second conductive pads of any one or more of Examples 1-29 optionally includes forming a source pad configured to be coupled to a source contact of the semiconductor die and to a source terminal of the leadframe and forming a gate pad configured to be coupled to a gate contact of the semiconductor die and to a gate terminal of the leadframe.

In Example 31, the method of any one or more of Examples 1-30 optionally includes providing a recessed vision marker area in a second dielectric surface of the dielectric, and forming a vision marker in the recessed vision marker area in the second dielectric surface.

In Example 32, the method of any one or more of Examples 1-31 optionally includes providing semiconductor connector position information using the vision marker.

In Example 33, the providing the recessed vision marker area of any one or more of Examples 1-32 optionally includes providing a first recessed vision marker area and a second recessed vision marker area, and the forming the vision marker of any one or more of Examples 1-32 optionally includes forming a first vision marker in the first recessed vision marker area and forming a second vision marker in the second recessed vision marker area.

In Example 34, a method of forming a semiconductor connector includes providing a dielectric wafer configured to be activated to conductive plating deposition using laser ablation, creating a first recessed pad area in a first surface of a dielectric and a second recessed pad area in the first surface of the dielectric using laser ablation of the first dielectric surface, forming a first pad in the first recessed pad area, the first pad configured to couple a first contact of a semiconductor die to a first terminal of a leadframe, and forming a second pad in the second recessed pad area, the second pad configured to couple a second contact of the semiconductor die to a second terminal of the leadframe.

In Example 35, the method of any one or more of Examples 1-34 optionally includes creating a recessed vision marker area in a second surface of the dielectric using laser ablation of the second dielectric surface, and forming a vision marker in the recessed vision marker area using conductive plating, the vision marker configured to provide semiconductor connector position information.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1-2 illustrate generally examples of a semiconductor connector.

FIG. 3 illustrates generally an example of a system including a semiconductor connector positioned over a semiconductor die and over a leadframe.

FIG. 4 illustrates generally an example of a system including a semiconductor package.

FIG. 5 illustrates generally an example of a system including a sawn wafer.

FIGS. 6-9 illustrate generally an example of forming a semiconductor connector.

FIGS. 10-15 illustrate generally an example of forming a semiconductor package.

### DETAILED DESCRIPTION

The present inventor has recognized, among other things, that a semiconductor connector can include a conductive pad formed in a recessed pad area of a dielectric configured to be activated to conductive plating deposition using laser ablation. In certain examples, the recessed pad area can include a laser ablated recessed pad area (e.g., the recessed pad area can be created using laser ablation of a surface of the dielectric), and the conductive pad (e.g., a copper (Cu) pad or other conductive pad) can include a laser activated conductive plating deposition (e.g., a laser activated Cu plating deposition or other conductive plating deposition) in the laser ablated recessed pad area.

In an example, the conductive pad can include a plurality of conductive pads (e.g., a source pad, a gate pad, etc.), and the shape or design of the conductive pad can be controlled or limited by a laser (e.g., a graphically computer aided laser ablator machine or other laser). Accordingly, the shape or design of the conductive pad can be flexible, allowing various semiconductor connector designs.

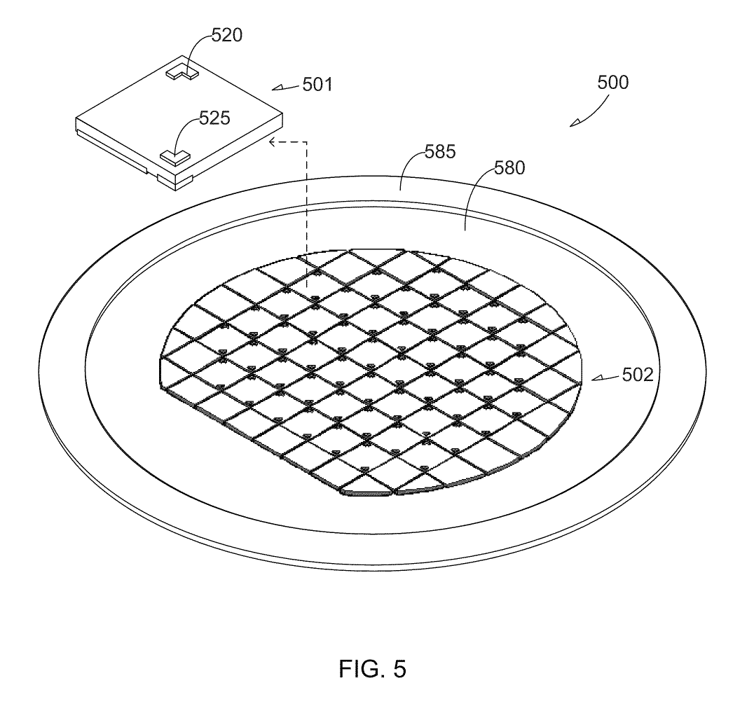

In an example, the semiconductor connector disclosed herein can provide connection to multiple terminals (e.g., a source terminal, a gate terminal, etc.) of a semiconductor die (e.g., a transistor, an integrated circuit (IC), a power MOSFET device, a driver IC, etc.), and can provide an alternative to copper clip bonding. In certain examples, the semiconductor connector disclosed herein can include a wafer level connector (see e.g., FIG. 5) and can be configured to utilize the space of a wafer ring area (e.g., using a circular wafer) and to conform to existing wafer sawing, die attach, or die handling systems or methods (e.g., providing easy handling, pick, placement, and alignment). In an example, the semiconductor connector disclosed herein can prolong saw blade life in wafer sawing systems by only cutting only wafer material and not conductive plating, and further, can reduce the number of sharp burrs formed from cutting conductive plating materials, which can cause problems during assembly. Further, in certain examples, a semiconductor connector having a copper (Cu) conductive pad can provide lower drain-to-source “ON” resistance (RDS_{ON}) than conventional wire bonding.

In an example, the semiconductor connector disclosed herein can be used in package having a smaller footprint or a thinner or lighter weight and can provide better connection alignment than a conventional leadframe based clip connectors, and can be applied to portable (e.g., ultraportable) products requiring condensed circuitry or small size.

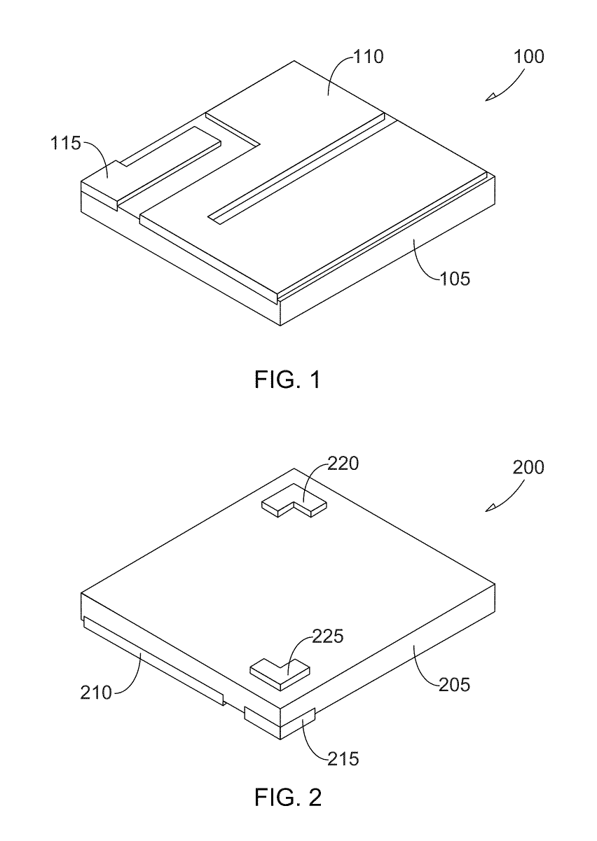

FIGS. 1-2 illustrate generally examples of a semiconductor connector including a dielectric having opposite first and second dielectric surfaces.

In an example, the dielectric can include a polymer or other dielectric activated to conductive plating deposition (e.g., Cu plating deposition) using laser ablation, such as thermoplastic, crosslink, an epoxy mold compound (EMC), polybutylene terephthalate (PBT), or one or more other dielectrics. In an example, the dielectric 105 can at least partially include a conductive component, such as one or more metallic compounds mixed into the dielectric material (e.g., an organometallic complex, etc.). In certain examples, the dielectric can be substantially reduced to the metallic compound, or otherwise activated to conductive plating deposition (e.g., Cu plating deposition), by irradiation with a laser (e.g., a CO₂ laser).

In other examples, the dielectric can include one or more other materials (e.g., a polymer matrix material including non-conductive polyacrylonitrile fibers) that, when subjected to laser irradiation, can carbonize, pyrolize, or otherwise decompose, to form a conductive network that can be converted to a desired metallization thickness by chemical or electroplating reinforcement.

In certain examples, the dielectric can be modified using a laser without a conductive phase forming locally, such as by creating catalytic centres on a dielectric material, or by using fine ceramic particles or catalytic micro-capsule or other fillers that can serve as sees for a following metallization process. Further, in various examples, the dielectric 105 can include an at least partially translucent mold compound, allowing visibility of one or more other features or components of the semiconductor connector, reducing the need for added fiducial markers for laser ablation reference, placement, or sawing.

FIG. 1 illustrates generally a semiconductor connector 100 including a first conductive pad 110 and a second conductive pad 115 on a first dielectric surface of a dielectric 105. In other examples, the semiconductor connector 100 can include a single conductive pad or a plurality of conductive pads (e.g., two or more than two). In an example, one or more conductive pads can be configured to couple at least one contact of a semiconductor die to at least one terminal of a leadframe.

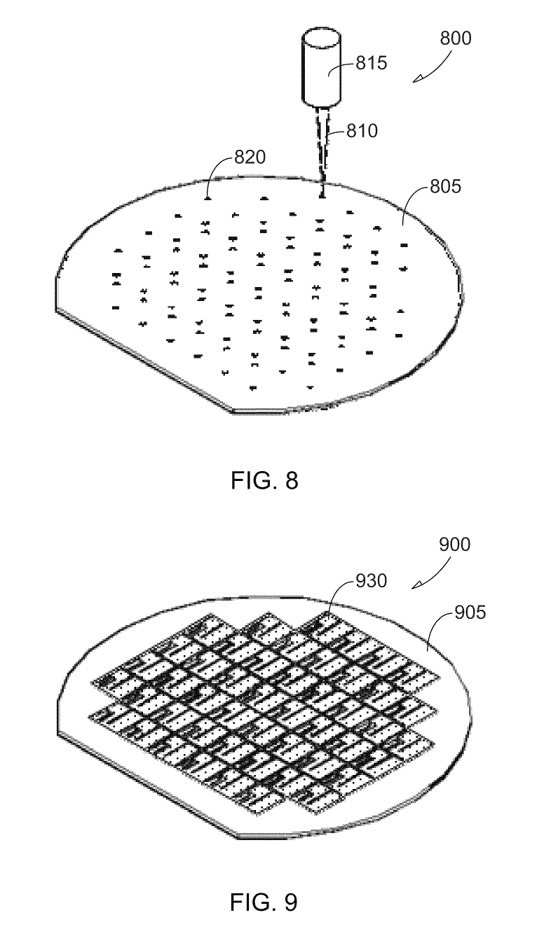

In an example, the dielectric 105 can include one or more recessed pad areas in the first dielectric surface (see e.g., FIGS. 7-8), and one or more conductive pad can be configured to be located in the one or more recessed pad areas. In certain examples, the one or more recessed pad areas can include a laser ablated recessed pad area (e.g., the recessed pad area can be created using laser ablation of the first dielectric surface), and the one or more conductive pads can include a laser activated conductive plating deposition (e.g., a laser activated Cu plating deposition, or one or more other plating depositions) in the laser ablated recessed pad area.

In an example, the first conductive pad 110 can include a first shape in a first recessed pad area in the first dielectric surface, and the second conductive pad 115 can include a second shape in a second recessed pad area in the first dielectric surface. In an example, the first shape can correspond to (e.g., be equivalent or similar to) the second shape. In other examples, the first shape can be different than the second shape.

In an example, the first conductive pad 110 (e.g., a source pad) can be configured to couple a first contact (e.g., a source contact, etc.) of a semiconductor die (e.g., a transistor) to a first terminal (e.g., a source terminal) of a leadframe, and the second conductive pad 115 (e.g. a gate pad) can be configured to couple a second contact (e.g., a gate contact) of the semiconductor die to a second terminal (e.g., a gate terminal) of the leadframe.

In other examples, one or more of the first conductive pad 110, the second conductive pad 115, or one or more other conductive pads can be configured to couple one or more contacts of a semiconductor die to one or more terminals of a leadframe (e.g., at least one terminal of a semiconductor package). In an example, the first conductive pad 110 can include multiple conductive pads for connecting multiple semiconductor die or multiple leadframes.

FIG. 2 illustrates generally an example of a semiconductor connector 200 including a first vision marker 220 and a second vision marker 225 on a second dielectric surface of a dielectric 205. In other examples, the semiconductor connector 200 can include a single vision marker or a plurality of vision markers (e.g., two or more than two). In an example, one or more vision markers can be configured to provide semiconductor connector position information (e.g., to a user, a machine, etc.).

In an example, the dielectric 205 can include one or more recessed vision marker areas in the second dielectric surface (see e.g., FIGS. 7-8), and one or more vision markers can be configured to be located in the one or more recessed vision marker areas. In certain examples, the one or more recessed vision marker areas can include a laser ablated recessed vision marker area (e.g., the recessed vision marker area can be created using laser ablation of the second dielectric surface), and the one or more vision markers can include a laser activated conductive plating deposition (e.g., a laser activated Cu plating deposition, or one or more other plating depositions) in the laser ablated recessed vision marker area.

In an example, the first vision marker 220 can include a first shape in a first recessed vision marker area in the second dielectric surface, and the second vision marker 225 can include a second shape in a second recessed vision marker area in the second dielectric surface. In an example, the first shape can correspond to (e.g., be equivalent or similar to) the second shape. In other examples, the first shape can be different than the second shape (e.g., to provide different position information).

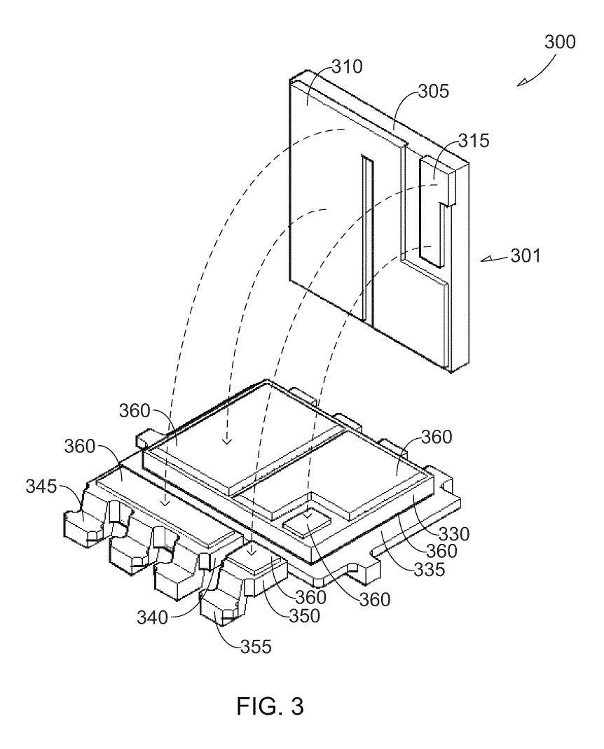

FIG. 3 illustrates generally an example of a system 300 including a semiconductor connector 301 positioned over a semiconductor die 330 and over a leadframe. In an example, the semiconductor connector 301 can include a dielectric 305, and a first conductive pad 310 and a second conductive pad 315 on a first dielectric surface of the dielectric 305. In an example, the leadframe can include a die attached pad (DAP) 335 (e.g., a drain terminal), a source lead post 340 having a source terminal 345, and a gate lead post 350 having a gate terminal 355.

In an example, the semiconductor connector 301 can be coupled to the semiconductor die 330 and to the gate lead post 340 and the source lead post 350, and the semiconductor die 330 can be coupled to the DAP 335, using solder 360 or one or more other fusible metal or alloy (e.g., conductive solder paste or epoxy having a lead (Pb) based or a PB free material). In an example, the first conductive pad 310 can be configured to couple a first contact (e.g., a source contact) of the semiconductor die 330 to the source lead post 340, and the second conductive pad 315 can be configured to couple a second contact (e.g., a gate contact) of the semiconductor die 330 to the gate lead post 350. In other examples, one or more other semiconductor connector, semiconductor die, or leadframe combinations can be used.

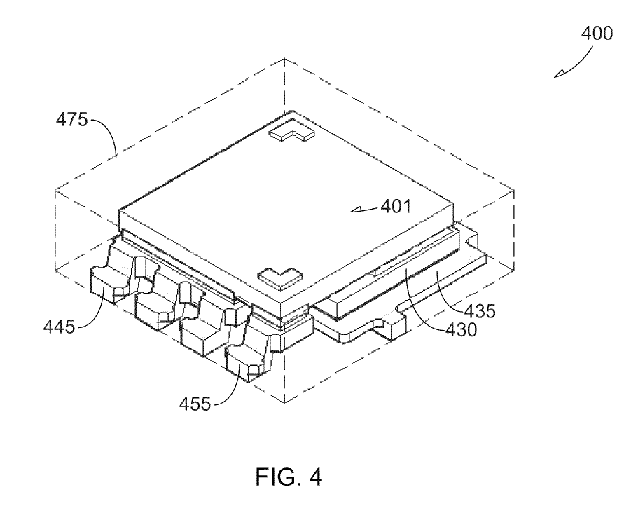

FIG. 4 illustrates generally an example of a system 400 including a semiconductor package 475 encapsulating a semiconductor die 430 coupled to a first portion of a leadframe, including a DAP 435, directly, and coupled to a second portion of the leadframe, including a source terminal 445 and a gate terminal 455, using a semiconductor connector 401. In other examples, one or more other semiconductor packages having one or more other semiconductor connector, semiconductor die, or leadframe combinations can be used.

FIG. 5 illustrates generally an example of a system 500 including a sawn wafer 502 on UV tape 580 of a wafer ring 585. In the example of FIG. 5, the sawn wafer 502 includes a plurality of sawn wafer level semiconductor connectors (e.g., semiconductor connector 501), each including first and second vision markers (e.g., first vision marker 520 and second vision marker 525). In an example, the UV tape 580 can aid in insuring that the wafer 502 does not break during pin aided ejection. In an example, the semiconductor connector 501 can be sawn to a specific size, and can be applied to a single die or to multiple dies, as well as molded packages (panel molded units, individual molded units, etc.) of any lead terminal configuration (e.g., leaded, leadless, etc.).

### Semiconductor Connector Process Examples

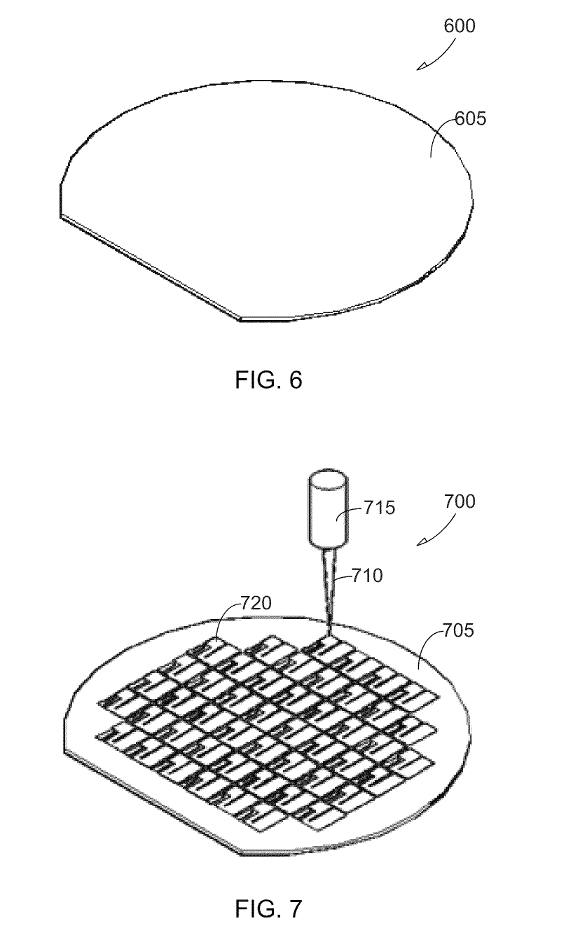

FIGS. 6-9 illustrate generally an example of forming a semiconductor connector.

FIG. 6 illustrates generally an example of a process step 600 including providing a wafer 605. In an example, the wafer 605 can include a dielectric (e.g., the dielectric 105, 205, etc.). In certain examples, the wafer 605 can be prepared using a molding process with laser ablation activated epoxy mold compound (EMC) or polybutylene terephthalate (PBT) as a base material (e.g., thermoplastic, crosslink, etc.).

FIG. 7 illustrates generally an example of a process step 700 including applying laser 710 to a surface of a dielectric 705 to provide at least one recessed area in the dielectric 705 using a laser head 715 (e.g., using laser ablation). In the example of FIG. 7, the at least one recessed area can include a recessed pad area 720. Although the example of FIG. 7 illustrates a plurality of outlines of recessed areas, the entire area within each outline can be removed or ablated.

In certain examples, the dielectric 705 can include a fully dielectric material, or a dielectric material having a metallic or other component. In an example, the dielectric 705 can be activated to conductive plating deposition using laser ablation.

FIG. 8 illustrates generally an example of a process step 800 including applying laser 810 to a surface of a dielectric 805 to provide at least one recessed area in the dielectric 805 using a laser head 815. In the example of FIG. 8, the at least one recessed area can include a recessed vision marker area 825. Although the example of FIG. 8 illustrates a plurality of outlines of recessed areas, the entire area within each outline can be removed or ablated.

In certain examples, the dielectric 805 can include a fully dielectric material, or a dielectric material having a metallic or other component. In an example, the dielectric 805 can be activated to conductive plating deposition using laser ablation.

FIG. 9 illustrates generally an example of a process step 900 including forming at least one conductive pad (e.g., a conductive pad 930) in at least one recessed pad area in a surface of a dielectric 905 using laser activated conductive plating. In certain examples, conductive plating solution can settle on areas activated using laser ablation (e.g., the dotted areas in FIG. 9). Then, the surface of the conductive plating or dielectric can be cleaned and dried. In an example, the conductive plating can include Cu plating, finish plating, or one or more other conductive plating (e.g., using one or more other electroless or electroplating processes). In certain examples, the top surface of the conductive plating can include pure Cu, or can be plated with a protective coating to enhance connection strength to a semiconductor die or leadframe (e.g., Ni, NiPdAu, Ag, or other protective coating configured to protect Cu from oxidation).

In an example, laser ablation of the dielectric 905 can free seeds on the surface of the material, enabling selective wet-chemical reduction metal precipitation. In other examples, one or more other methods utilizing laser ablation can be used to form the conductive pad.

In an example, at least one vision marker can be formed in at least one recessed vision marker area in a surface of the dielectric 905 using laser activated conductive plating. In an example, the shape of one or more of the recessed areas, conductive pads, or vision markers can be user-configurable (e.g., depending on specific design constraints). In an example, the shape or pattern is limited only by the constraints of the laser, eliminating the need for different mask sets for various patterns of plated surfaces. Further, finished semiconductor connectors can be singulated (e.g., sawn), picked, and placed using existing wafer related systems and methods.

In certain examples, one or more of process steps 600-900 can be excluded, or one or more other process steps or variations can be introduced to those described above.

### Semiconductor Package Process Examples

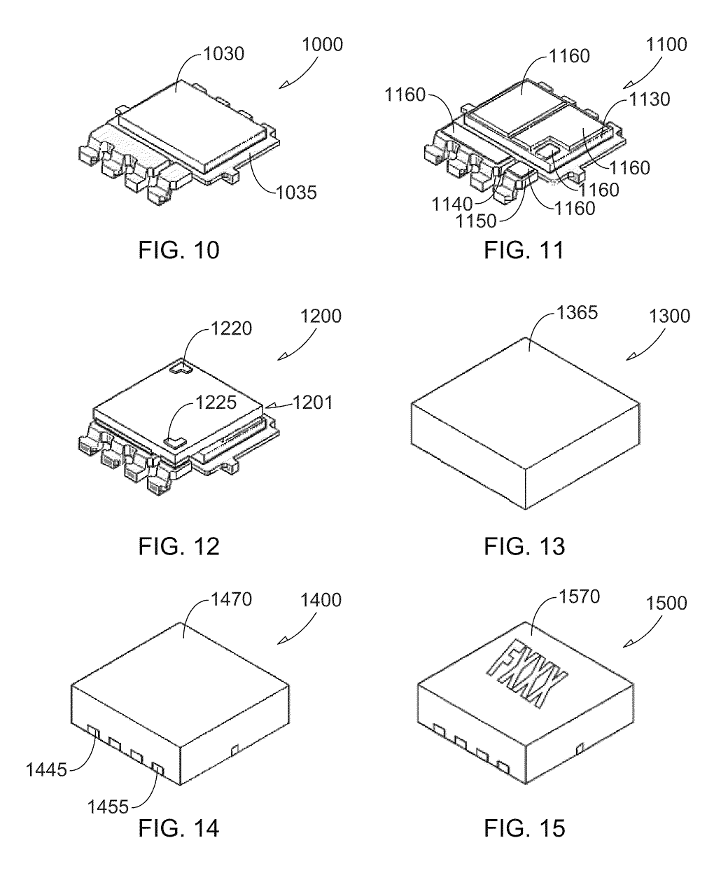

FIGS. 10-15 illustrate generally an example of forming a semiconductor package.

FIG. 10 illustrates generally an example of a process step 1000 including attaching a semiconductor die 1030 to a die attached pad (DAP) 1035 of a leadframe using solder (e.g., die attach (D/A) solder).

FIG. 11 illustrates generally an example of a process step 1100 including dispensing solder 1160 on a semiconductor die 1130, on a source lead post 1140, and on a gate lead post 1150.

FIG. 12 illustrates generally an example of a process step 1200 including attaching a semiconductor connector 1201 to a semiconductor die and to a leadframe. In an example, the semiconductor connector 1201 can include a first vision marker 1220 and a second vision marker 1225 configured to provide connector position information. In an example, a surface of the semiconductor die can be coplanar with a surface of a leadframe. In other examples, one or more of the semiconductor die or the leadframe can include a large step. Accordingly, the semiconductor connector 1201 can be planar or coplanar.

FIG. 13 illustrates generally an example of a process step 1300 including molding a semiconductor package 1365, including encapsulating a semiconductor die, a semiconductor connector, and a leadframe in a dielectric.

FIG. 14 illustrates generally an example of a process step 1400 including providing a singulated semiconductor package 1470, including sawing a molded semiconductor package to expose one or more terminals of a leadframe (e.g., a source terminal 1445, a gate terminal 1455, or one or more other terminals). In an example, the semiconductor package 1470 can include a board mounting external terminal of a leadless terminal, a leaded terminal, a lead formed terminal, or a ball terminal. In an example, the semiconductor connector disclosed herein can be combined with standard wire bonding, providing belt and suspender connection. Further, in certain examples, multiple semiconductor connectors can be included in a single semiconductor package, or a single semiconductor connector can be used for multiple semiconductor dies. In other examples, the semiconductor connector disclosed herein can be used on one semiconductor die, and wire bonding can be used on another.

FIG. 15 illustrates generally an example of a process step 1500 including marking a semiconductor package 1570. In certain examples, following singulation, the semiconductor package 1570 can be tested or packaged (e.g., tape and reel).

In certain examples, one or more of process steps 1000-1500 can be excluded, or one or more other process steps or variations can be introduced to those described above.

### Additional Notes

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In other examples, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

1. A semiconductor connector, comprising:
a dielectric having a first dielectric surface and a second dielectric surface opposite the first dielectric surface, the dielectric configured to be activated to copper (Cu) plating deposition using laser ablation;
a first pad having a first shape in a first recessed pad area in the first dielectric surface, the first pad configured to couple a first contact of a semiconductor die to a first terminal of a leadframe;
a second pad having a second shape in a second recessed pad area in the first dielectric surface, the second shape different than the first shape, and the second pad configured to couple a second contact of the semiconductor die to a second terminal of the leadframe;
a vision marker in a recessed vision marker area in the second dielectric surface;
wherein the first and second recessed pad areas includes respective first and second recesses created using laser ablation of the first dielectric surface, and wherein the recessed vision marker area includes a recess created using laser ablation of the second dielectric surface; and
wherein the first pad, the second pad, and the vision marker include laser activated Cu plating depositions.

2. The semiconductor connector of claim 1, wherein the vision marker is configured to provide semiconductor connector position information.

3. The semiconductor connector of claim 1, wherein the vision marker includes separate first and second vision markers configured to provide semiconductor connector position information.

4. The semiconductor connector of claim 1, wherein the first pad includes a source pad configured to be coupled to a source contact of the semiconductor die and to a source terminal of the leadframe; and
wherein the second pad includes a gate pad configured to be coupled to a gate contact of the semiconductor die and to a gate terminal of the leadframe.

5. The semiconductor connector of claim 1, wherein the semiconductor connector includes a wafer-level semiconductor connector, and wherein the wafer-level semiconductor connector is one of a plurality of wafer-level semiconductor connectors on a single wafer; and
wherein each of the wafer-level semiconductor connectors includes a vision marker configured to provide a boundary for the wafer-level semiconductor connector in relation to the plurality of wafer-level connectors on the single wafer.

6. A semiconductor connector, comprising:
a dielectric having a first dielectric surface and a second dielectric surface opposite the first dielectric surface, the dielectric configured to be activated to conductive plating deposition using laser ablation; and
a conductive pad in a recessed pad area in the first dielectric surface, the conductive pad configured to couple at least one contact of a semiconductor die to at least one terminal of a leadframe.

7. The semiconductor connector of claim 6, wherein the recessed pad area includes a recess created using laser ablation of the first dielectric surface; and
wherein the conductive pad includes a laser activated conductive plating deposition in the recessed pad area.

8. The semiconductor connector of claim 7, wherein the dielectric includes a polymer configured to be activated to copper (Cu) plating deposition using laser ablation; and
wherein the conductive pad includes a laser activated Cu plating deposition.

9. The semiconductor connector of claim 6, including a vision marker in a recessed vision marker area in the second dielectric surface; and
wherein the vision marker includes a laser activated conductive plating deposition in the recessed vision marker area.

10. The semiconductor connector of claim 9, wherein the dielectric includes a polymer configured to be activated to copper (Cu) plating deposition using laser ablation; and
wherein the vision marker includes a laser activated Cu plating deposition.

11. The semiconductor connector of claim 9, wherein the vision marker includes a first and a second vision marker configured to provide semiconductor connector position information.

12. The semiconductor connector of claim 6, wherein the conductive pad includes:
a first conductive pad having a first shape in a first recessed pad area in the first dielectric surface;
a second conductive pad having a second shape in a second recessed pad area in the first dielectric surface, the second shape different than the first shape; and
wherein the first and second conductive pads are configured to couple first and second contacts of the semiconductor die to respective first and second terminals of the leadframe.

13. The semiconductor connector of claim 12, wherein the first conductive pad includes a source pad configured to be coupled to a source contact of the semiconductor die and to a source terminal of the leadframe; and
wherein the second conductive pad includes a gate pad configured to be coupled to a gate contact of the semiconductor die and to a gate terminal of the leadframe.

14. The semiconductor connector of claim 6, wherein the dielectric includes at least one of an epoxy mold compound (EMC), polybutylene terephthalate (PBT), thermoplastic, or crosslink.

15. The semiconductor connector of claim 6, wherein the semiconductor connector includes a wafer-level semiconductor connector, and wherein the wafer-level semiconductor connector is one of a plurality of wafer-level semiconductor connectors on a single wafer; and
wherein each of the wafer-level semiconductor connectors includes a vision marker configured to provide a boundary for the wafer-level semiconductor connector in relation to the plurality of wafer-level connectors on the single wafer.

16. A system comprising:
a semiconductor die having a plurality of electrical contacts;
a leadframe having a plurality of terminals; and
a semiconductor connector configured to couple at least one of the plurality of electrical contacts of the semiconductor die to at least one of the plurality of terminals of the leadframe, the semiconductor connector including:
a dielectric having a first dielectric surface and a second dielectric surface opposite the first dielectric surface, the dielectric configured to be activated to conductive plating deposition using laser ablation; and
a conductive pad in a recessed pad area in the first dielectric surface, the conductive pad configured to couple the at least one of the plurality of electrical contacts of the semiconductor die to the at least one of the plurality of terminals of the leadframe.

17. The system of claim 16, wherein the recessed pad area includes a recess created using laser ablation of the first dielectric surface; and
wherein the conductive pad includes a laser activated conductive plating deposition in the recessed pad area.

18. The system of claim 16, including a vision marker in a recessed vision marker area in the second dielectric surface; and
wherein the vision marker includes a laser activated conductive plating deposition in the recessed vision marker area.

19. The system of claim 16, wherein the conductive pad includes:
a first conductive pad having a first shape in a first recessed pad area in the first dielectric surface;
a second conductive pad having a second shape in a second recessed pad area in the first dielectric surface, the second shape different than the first shape; and
wherein the first and second conductive pads are configured to couple first and second contacts of the semiconductor die to respective first and second terminals of the leadframe.

20. The system of claim 19, wherein the semiconductor die includes a source contact, wherein the leadframe includes a source terminal, and wherein the first conductive pad includes a source pad configured to be coupled to the source contact and to the source terminal; and
wherein the semiconductor die includes a gate contact, wherein the leadframe includes a gate terminal, and wherein the second conductive pad includes a gate pad configured to be coupled to the gate contact to the gate terminal.
